(19) United States
(12) Patent Application Publication
(10) Pub. No.: US 2002/0149120 A1
(43) Pub. Date: Oct. 17, 2002

(54) Semiconductor device having TEG elements

(75) Inventor: Kazuki Sugiyama, Tokyo (JP)

Correspondence Address: FOLEY AND LARDNER, SUITE 500, 3000 K STREET NW, WASHINGTON, DC, 20007, US

(73) Assignee: NEC CORPORATION

(21) Appl. No.: 10/119,904

(22) Filed: Apr. 11, 2002

(30) Foreign Application Priority Data
Apr. 12, 2001 (JP) 2001-114011

(51) Int. Cl. H01L 23/544; H01L 29/40; H01L 23/48; H01L 23/52

(52) U.S. Cl. 257/786; 257/620; 257/621

(57) ABSTRACT

A semiconductor wafer includes a plurality of semiconductor chips and a plurality of scribe lines for dividing the semiconductor chips from one another. The semiconductor chip includes a bonding pad and an underlying TEG element for monitoring diffused regions of normal transistor or interconnect patterns in the semiconductor chip.

### BACKGROUND OF THE INVENTION

(a) Field of the Invention

The present invention relates to a semiconductor device having a test element group (TEG) including a plurality of TEG elements and, more particularly, to a technique for locating the TEG elements on the semiconductor wafer.

(b)Description of the Related Art

In fabrication of the chips of semiconductor devices on a semiconductor wafer, the number of semiconductor chips fabricated on the wafer has been increased by reducing the dimensions of the semiconductor chips to lower the cost for the semiconductor devices.

On the other hand, semiconductor chip generally includes TEG elements which are used for analyzing the element characteristics or defects of the diffused regions or interconnect patterns of the semiconductor chips after the fabrication process. Example of the TEG elements includes a transistor pattern having diffused regions within the semiconductor substrate and an interconnect pattern overlying the semiconductor substrate, for monitoring the diffusion steps or the patterning steps for the normal elements or normal interconnects of the semiconductor chip. The TEG elements are subjected to measurements of electric characteristics of the normal elements or normal interconnect patterns by using associated TEG pads electrically connected to and generally overlying the TEG elements.

It is important to locate the TEG elements in the semiconductor chip while arranging normal elements and normal interconnects substantially without increasing the dimensions of the semiconductor chip. In general, the TEG elements are arranged in a dedicated area or limited spaces of the chip.

In the conventional technique, the area for the TEG elements prevents the semiconductor chip from achieving further reduced dimensions, irrespective of whether the TEG elements are located in the dedicated area or the limited spaces of the chip. In addition, the TEG elements located in the limited spaces are not suited to the effective analysis of the defects or electric characteristics after the fabrication process due to the difficulty in the measurements.

### SUMMARY OF THE INVENTION

It is therefore an object of the present invention to provide a semiconductor device having TEG elements which are suited to effective analysis of the electric characteristics or defects caused in diffusions steps or patterning steps and do not substantially increase the dimensions of the semiconductor chip.

It is another object of the present invention to provide a semiconductor wafer mounting thereon such a semiconductor device during the fabrication process of the semiconductor device.

The present invention provides a semiconductor chip including normal elements, bonding pads connected to the normal elements, and at least one TEG element underlying the bonding pad.

The present invention also provides a semiconductor wafer including a semiconductor substrate, a plurality of semiconductor chips formed on the semiconductor substrate, a plurality of scribe lines separating the semiconductor chips from one another, at least one TEG element for monitoring a part of one of the semiconductor chips, and at least one TEG pad connected to the TEG element and disposed in an area for the scribe lines.

In accordance with the semiconductor chip of the present invention, the TEG element underlying the bonding pad or having a TEG pad disposed in the area for the scribe lines reduces the dimensions of the semiconductor chip and lowers the cost for the semiconductor chip.

The above and other objects, features and advantages of the present invention will be more apparent from the following description, referring to the accompanying drawings.

### BRIEF DESCRIPTION OF THE DRAWINGS

FIG. 1 is a partial top plan view of a semiconductor wafer mounting thereon a plurality of semiconductor chips according to a first embodiment of the present invention.

FIG. 2 is a partial top plan view of a semiconductor wafer mounting thereon a plurality of semiconductor chips according to a second embodiment of the present invention.

FIG. 3 is a partial top plan view of a semiconductor wafer mounting thereon a plurality of semiconductor chips according to a third embodiment of the present invention.

### PREFERRED EMBODIMENTS OF THE INVENTION

Now, the present invention is more specifically described with reference to accompanying drawings, wherein similar constituent elements are designated by similar reference numerals.

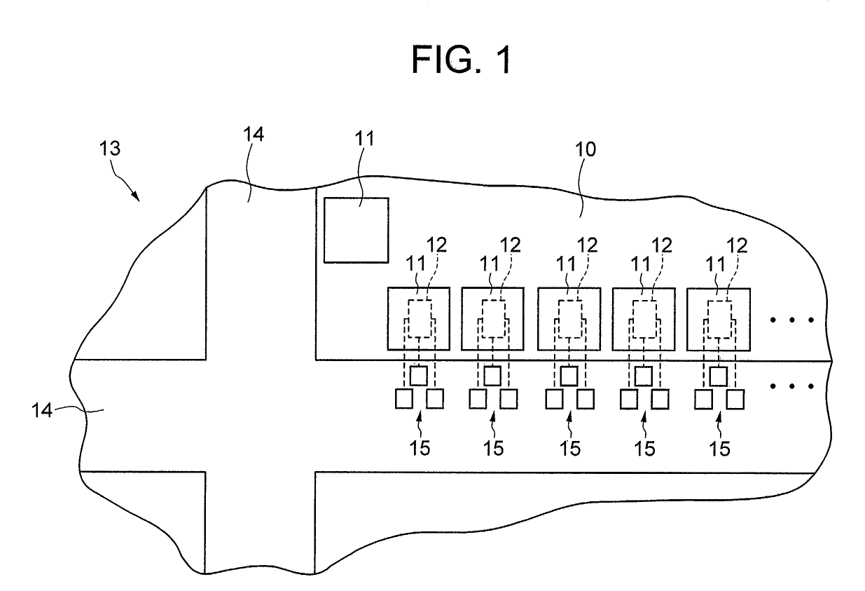

Referring to FIG. 1, a semiconductor wafer, generally designated by numeral 13, mounts thereon a plurality of semiconductor chips 10, according to a first embodiment of the present invention, formed on a semiconductor substrate. The wafer 13 includes a plurality of scribe lines 14 extending column and row directions for dividing the wafer 13 into a plurality of semiconductor chips 10. The scribe lines 14 are used for separating the semiconductor chips 10 from one another 10 by using a dicing member after fabrication and testing of the semiconductor chips.

Each semiconductor chip 10 includes a plurality of bonding pads 11 arranged along the periphery of the each semiconductor chip 10. A plurality of TEG elements 12 for monitoring normal elements, such as transistor elements, are disposed underlying the respective bonding pads 11. Three TEG pads 15 are disposed on the scribe lines 14 corresponding to each TEG element 11.

Each TEG element 12 is formed for monitoring the diffused regions of a transistor, such as a MOSFET, formed in the semiconductor substrate and is located right under the corresponding bonding pad 11. The TEG element 12 is connected to the corresponding TEG pads 15 through via-holes and 1 interconnects which underlie a via-hole for the corresponding bonding pad 11. The TEG pads 15 are used for measurements of the electric characteristics of the diffused regions or detecting the defects of the interconnect pattern before dicing the wafer 13 along the scribe lines 14.

In the semiconductor device, by using the area underlying the bonding pads 11, the TEG elements 12 do not substantially increase the chip area, differently from the conventional techniques wherein the TEG elements are disposed in the dedicated area or the limited spaces.

In addition, by disposing the TEG pads 15 on the scribe lines 14, the area for the TEG pads 15 do not increase the chip area either.

The above configurations of the semiconductor chip 10 of the present embodiment allow a larger number of TEG elements 12 to be located in the semiconductor chip 10 without providing a dedicated area. Thus, the effective area of the chip can be increased without increasing the chip area itself. The larger number of the TEG elements 12 allows a larger amount of information to be obtained during the analysis of the characteristics or defects after the diffusion steps and the patterning steps.

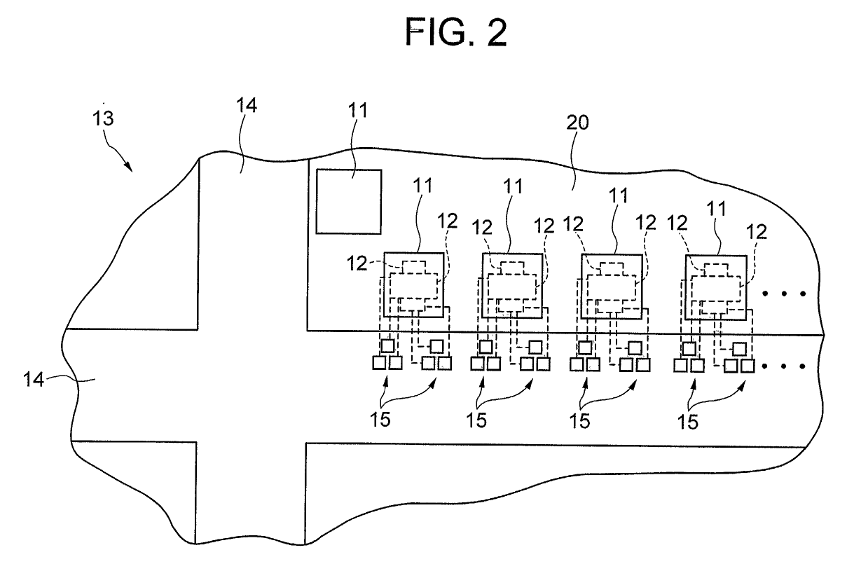

Referring to FIG. 2, in a semiconductor wafer 13 mounting thereon a plurality of semiconductor chips 20 according to a second embodiment of the present invention, a plurality of (two, in this example) TEG elements 12 are disposed underlying the bonding pad 11 for monitoring the diffused regions and the interconnect pattern, for example. The other configurations of the wafer in the present embodiment is similar to those in FIG. 1.

Since the two TEG elements 12 underlying a single bonding pad 11 are not disposed in adjacent layers and do not affect each other, the two TEG elements 12 can be disposed underlying the same bonding pad 11. These two TEG elements 12 are connected through via-holes and interconnects to respective TEG pads 15 disposed on the scribe line 14.

By providing a plurality of TEG elements 12 right under a single bonding pad 11, a further larger number of TEG elements 12 can be disposed in a single chip 20. The two TEG elements 12 should be disposed in different layers and do not affect each other without using a common via-hole.

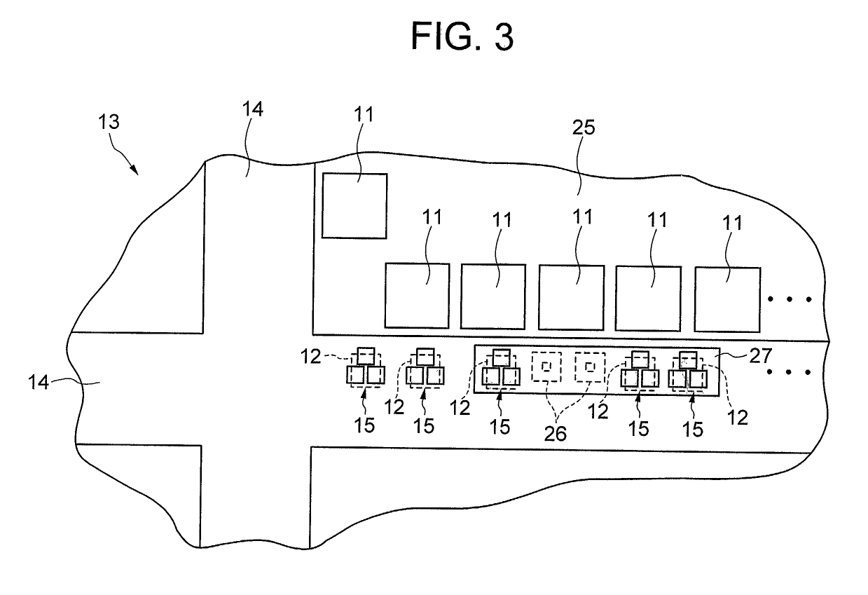

Referring to FIG. 3, a wafer 13 mounting thereon a plurality of semiconductor chips 25 according to a third embodiment of the present invention includes a plurality of TEG elements 12 as well as corresponding TEG pads 15 disposed on the scribe line 14. The TEG elements 12 are disposed in the vicinity of the bonding pads 11 arranged along the periphery of the semiconductor chip 10. The TEG pads 15 overlie the respective TEG elements 12.

In FIG. 3, some TEG elements 12 are disposed in an area 27 of the scribe line 14 for receiving therein an accessory pattern 26, such as an alignment mark or a reference pattern. The alignment mark is used for positioning of a pattern with respect to the chip 10, whereas the reference pattern is used for alignment of two or more patterns in the chip 10. The TEG elements 12 may be disposed as underlying or overlying the accessory pattern 26. This configuration also reduces the chip area.

Since the above embodiments are described only for examples, the present invention is not limited to the above embodiments and various modifications or alterations can be easily made therefrom by those skilled in the art without departing from the scope of the present invention.

What is claimed is:

1. A semiconductor chip comprising normal elements, bonding pads connected to said normal elements, and at least one TEG element underlying said bonding pad.

2. The semiconductor chip as defined in claim 1, wherein a plurality of said TEG elements underlie said bonding pad.

3. The semiconductor chip as defined in claim 1, wherein said bonding pads are disposed in a vicinity of a periphery of said semiconductor chip.

4. The semiconductor chip as defined in claim 1, wherein said TEG element includes a plurality of diffused regions.

5. The semiconductor chip as defined in claim 1, wherein said TEG element is an interconnect pattern.

6. A semiconductor wafer comprising a semiconductor substrate, a plurality of semiconductor chips formed on said semiconductor substrate, a plurality of scribe lines separating said semiconductor chips from one another, at least one TEG element for monitoring a part of one of said semiconductor chips, and at least one TEG pad connected to said TEG element and disposed in an area for said scribe lines.

7. The semiconductor wafer as defined in claim 6, wherein said TEG element is disposed in said area for said scribe lines.

8. The semiconductor wafer as defined in claim 7, wherein said TEG element underlies or overlies an accessory pattern formed in said area for said scribe line.

9. The semiconductor wafer as defined in claim 6, wherein said TEG element is disposed in said semiconductor chip, and underlies a bonding pad.
